(19) United States
(12) Patent Application Publication
(10) Pub. No.: US 2014/0227887 A1
(43) Pub. Date: Aug. 14, 2014

(54) PHENOL-BASED SELF-CROSSLINKING POLYMER AND RESIST UNDERLAYER FILM COMPOSITION INCLUDING SAME

(71) Applicant: DONGJIN SEMICHEM CO., LTD., Incheon (KR)

(72) Inventors: Jeong-Sik Kim, Hwaseong-si (KR); Jae-Hyun Kim, Seoul (KR); Jae-Woo Lee, Bucheon-si (KR)

(21) Appl. No.: 14/343,115

(22) PCT Filed: Sep. 5, 2012
(86) PCT No.: PCT/KR2012/007102

§ 371 Date: Mar. 6, 2014

(30) Foreign Application Priority Data
Sep. 6, 2011 (KR) 10-2011-0090126

(51) Int. Cl. H01L 21/027

(52) U.S. Cl. CPC H01L 21/0271
USPC 438/781; 528/162; 528/152; 528/125; 528/205; 524/595; 524/594; 524/592; 524/317

(57) ABSTRACT

A phenolic self-crosslinking polymer whose self-crosslinking reaction at a heating step is performed without additives for hardening the polymer, and a composition of resist-underlayer-film containing the same, are disclosed. The phenolic self-crosslinking polymer being selected from a group consisting of a polymer represented by Formula 1, a polymer represented by Formula 2 and a polymer represented by Formula 3:

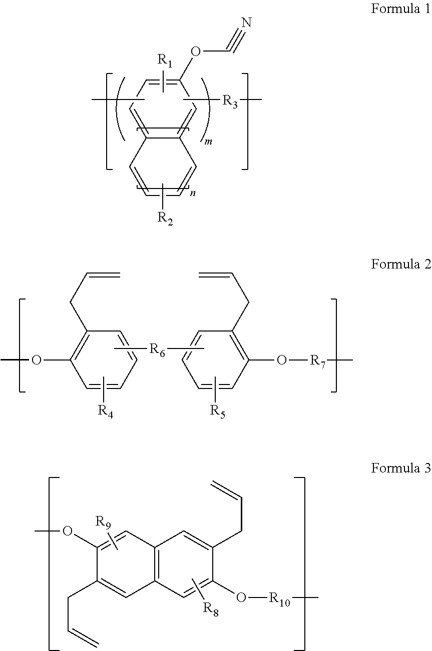

### REFERENCE TO RELATED APPLICATIONS

This application is a U.S. National Phase application of International Application No. PCT/KR2012/007102, filed Sep. 5, 2012, and claims priority to Korean Patent Application No. 10-2011-0090126, filed Sep. 6, 2011, the disclosures of each of these applications being incorporated herein by reference in their entireties.

### FIELD OF THE INVENTION

This invention relates to a phenolic self-crosslinking polymer, and more particularly to a phenolic self-crosslinking polymer whose self-crosslinking reaction at a heating step is performed without additives for hardening the polymer, and a composition of resist-underlayer-film containing the same.

### BACKGROUND OF THE INVENTION

As a size of the semiconductor device reduces and circuit integration increases, the pattern of the semiconductor device becomes smaller. Thus, for preventing the photoresist pattern collapse, the thickness of photoresist layer and its pattern become thin. However, it is difficult to etch a layer by using the thin photoresist pattern, so between the photoresist layer(pattern) and the layer to be etched is introduced a layer of inorganic materials or organic materials, which is called as a resist-underlayer-film. The resist-underlayer-film process is to etch the layer to be etched by using a pattern of resist-underlayer-film after forming the pattern of resist-underlayer-film with the photoresist pattern thereon. The materials used for the resist-underlayer film are of silicon nitride, silicon oxynitride, polysilicon, titanium nitride, amorphous carbon and so on. Generally the resist-underlayer-film is manufactured by a chemical vapor deposition (CVD) process.

The resist-underlayer-film made by the CVD process has physical properties of high etch selectivity and etch resistivity. However, it has problems such as particle problems and initial investment costs. In order to solve these problems of CVD process, a spin-on-carbon composition is spin-coated to form a resist-underlayer-film (or spin-on-carbon underlayer). The spin-on carbon underlayer has a uniform coating property and improved surface roughness over the CVD process, as the carbon film is coated by a solution dispense process, though the etch resistivity thereof is not equal to that of the resist-underlayer-film by the CVD process. In addition, the spin-on-carbon coating process is advantageously economical because the initial investment cost thereof is less than that of the CVD process.

In order to form the spin-on-carbon underlayer, required is a composition which satisfies properties of the high etch selectivity, thermal stability, solubility to the conventional organic solvent, storage stability and adhesivity. As the composition of the spin-on-carbon underlayer satisfying the above stated properties, phenolic polymer is used having high carbon amounts, strong polarity and high thermal stability, and a study for the phenolic polymer had been variously and widely performed. During the conventional process for forming the spin-on-carbon underlayer, is introduced an additive for hardening, which may deteriorate the etch resistivity of the underlayer film. Also, the additives which do not participate with the hardening reaction in a high baking step, are sublimated to generate out-gassing, thereby contaminating the underlayer-film and the manufacturing instruments.

### SUMMARY OF THE INVENTION

Therefore, it is an object of the present invention to provide a phenolic-self crosslinking polymer whose self-crosslinking reaction at a heating(baking) step is performed without additives for hardening the polymer, to have good etch resistivity and little amount of out-gassing, and a composition of resist-underlayer-film containing the same.

In order to achieve these objects, the present invention provides a phenolic self-crosslinking polymer selected from a group consisting of a polymer represented by a following Formula 1, a polymer represented by a following Formula 2 and a polymer represented by a following Formula 3.

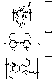

In Formulas 1 to 3, R1, R2, R4, R5, R8 and R9 each is independently a hydrogen atom or chain type, branch type, single ring type or multi-ring type, saturated or unsaturated hydrocarbon group of 1 to 20 carbon atoms, which contains or does not contain a hetero atom. R3, R7 and R10 each is independently chain type, branch type, single ring type or multi-ring type, saturated or unsaturated hydrocarbon group of 1 to 30 carbon atoms, which contain or does not contain a hetero atom. R6 is independently chain type, branch type, single ring type or multi-ring type, saturated or unsaturated hydrocarbon group of 1 to 40 carbon atoms. m is 1 or 2. When m is 2, each repeating unit of m is connected to each other directly or through chain type, branch type, single ring type or multi-ring type, saturated or unsaturated hydrocarbon group of 1 to 40 carbon atoms. n is an integer of 0 to 100.

The phenolic self-crosslinking polymer according to the present invention is prepared by substituting cyanate group for a hydrogen atom in hydroxyl group of the conventional phenolic polymer or by substituting allyl group for an alpha-hydrogen atom in hydroxyl group of the conventional phenolic polymer. The phenolic self-crosslinking polymer according to the present invention can be hardened without an additive such as a cross-linking agent, at a heating (baking) step so that it has good thermal stability. Therefore, composition for forming resist-underlayer-film according to the present invention, which is comprised by the present phenolic self-crosslinking polymer and an organic solvent, is suitable for the composition of the spin-on-carbon underlayer film which requires high thermal stability. The composition according to the present invention does not contain a curing agent so that there is no out-gassing or if any, very little, at a hardening step or backend process (about 400° C. heating). Also, the spin-on-carbon underlayer film has high etch selectivity by the self-crosslinking of the polymer, and good planarization at a gab-filling step.

### BRIEF DESCRIPTION OF THE DRAWINGS

FIG. 1 to FIG. 3 are drawings for showing TGA (Thermo Gravimetric Analysis) graphs of resist-underlayer-film samples according to Example 7, Example 11 and Comparative Example 1 of the present invention.

FIG. 4 to FIG. 6 are drawings for showing FE-SEM (Field Emission Scanning Electron Microscope) photographs of silicon wafer on which ISO (an isolated trench) pattern is formed, ISO pattern being is covered with composition of the resist-underlayer-film according to Example 7, Example 11 and Comparative Example 1 of the present invention.

FIG. 7 to FIG. 9 are drawings for showing FE-SEM (Field Emission Scanning Electron Microscope) photographs of silicon wafers each on which trench pattern is formed, the trench pattern being coated with composition of the resist-underlayer film according to Example 7, Example 11 and Comparative Example 1 of the present invention.

### DETAILED DESCRIPTION OF THE INVENTION

A more complete appreciation of the invention, and many of the attendant advantages thereof, will be better appreciated by reference to the following detailed description.

The phenolic self-crosslinking polymer according to the present invention is prepared by substituting cyanate group for hydrogen atom in hydroxyl group of the conventional phenolic polymer or by substituting allyl group for alpha-hydrogen atom in hydroxyl group of the conventional phenolic polymer. The phenolic self-crosslinking polymer according to the present invention is selected from a group consisting of a polymer represented by the following Formula 1, a polymer represented by the following Formula 2 and a polymer represented by the following Formula 3.

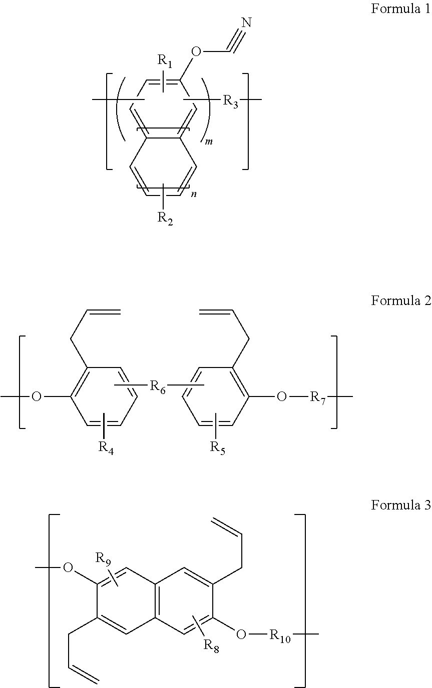

In Formulas 1 to 3, R1, R2, R4, R5, R8 and R9 each is independently a hydrogen atom or chain type, branch type, single ring type or multi-ring type, saturated or unsaturated hydrocarbon group of 1 to 20 carbon atoms, preferably 1 to 10 carbon atoms, which contains or does not contain a hetero atom such as an oxygen atom (0), a nitrogen atom (N), a sulfur atom (S) or mixture thereof. R3, R7 and R10 each is independently chain type, branch type, single ring type or multi-ring type, saturated or unsaturated hydrocarbon group of 1 to 30 carbon atoms, preferably 1 to 20 carbon atoms, which contain or does not contain hetero atoms of oxygen atoms, nitrogen atoms, sulfur atoms or mixture thereof. Examples of R3, R7 and R10 include

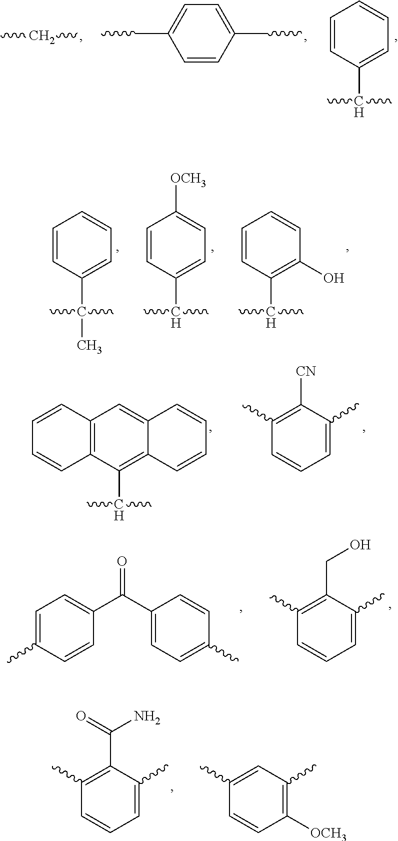

(wherein, [symbol] indicates a connecting bond). R6 is independently chain type, branch type, single ring type or multi-ring type, saturated or unsaturated hydrocarbon group of 1 to 40 carbon atoms, preferably 1 to 30 carbon atoms. Examples of R6 include

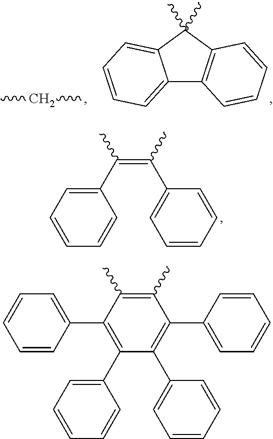

(wherein, [symbol] indicates a connecting bond). m is 1 or 2. When m is 2, each repeating unit of m is connected to each other directly or through chain type, branch type, single ring type or multi-ring type, saturated or unsaturated hydrocarbon group of 1 to 40 carbon atom, preferably 1 to 30 carbon atoms, for example, , , , (wherein, indicates a connecting bond). n is an integer of 0 to 100, preferably 0 to 50, more preferably 1 to 10.

Examples of polymer represented by Formula 1 include the polymers represented by following Formula 1a to Formula 1o.

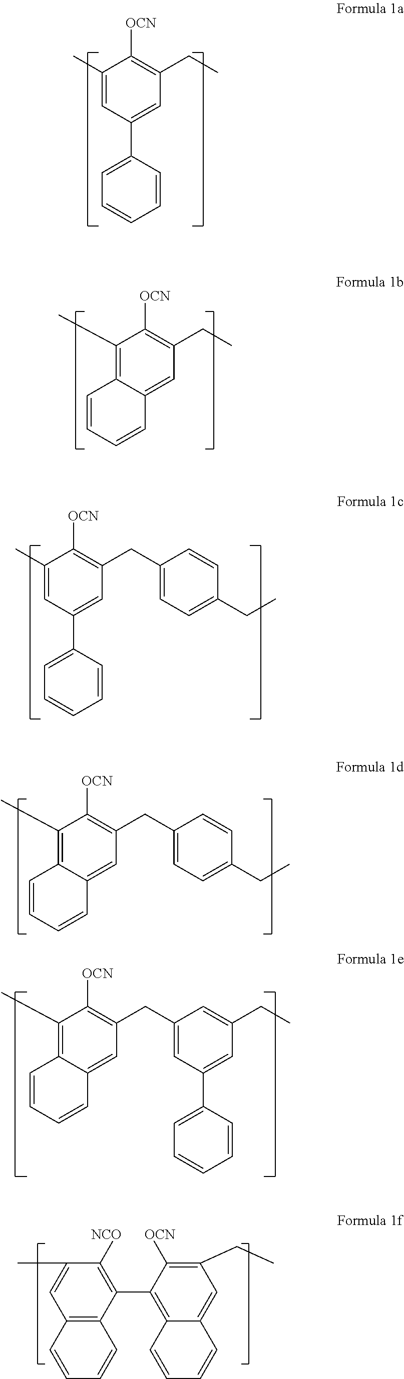

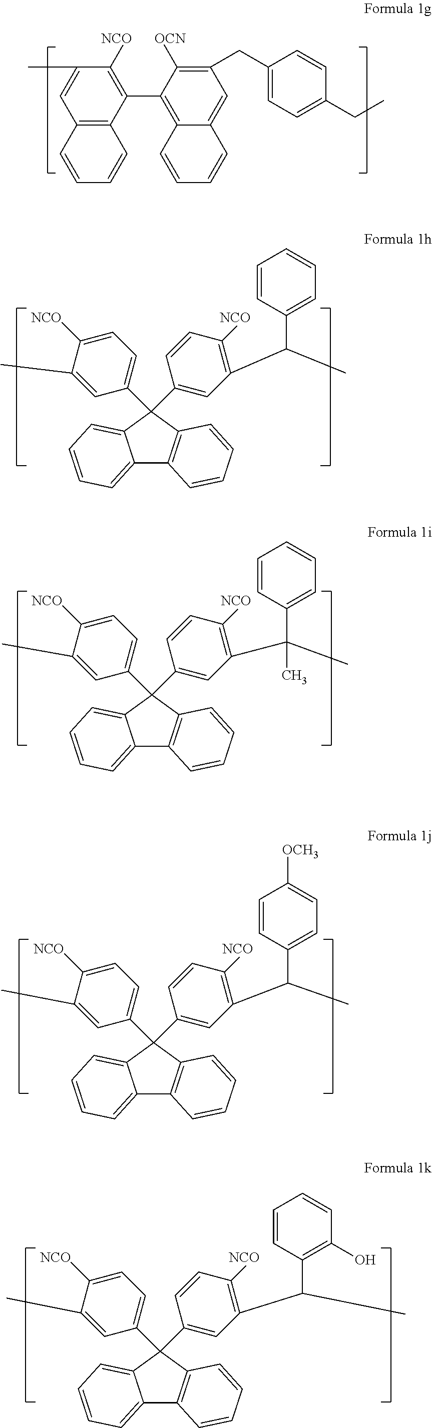

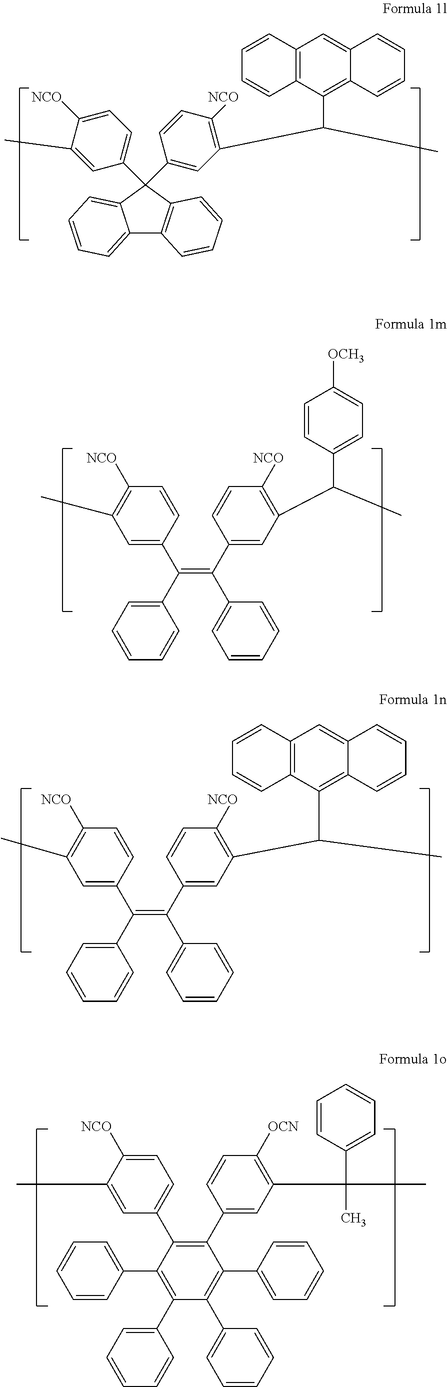

Examples of polymer represented by Formula 2 include the polymers represented by the following Formula 2a to Formula 2 g.

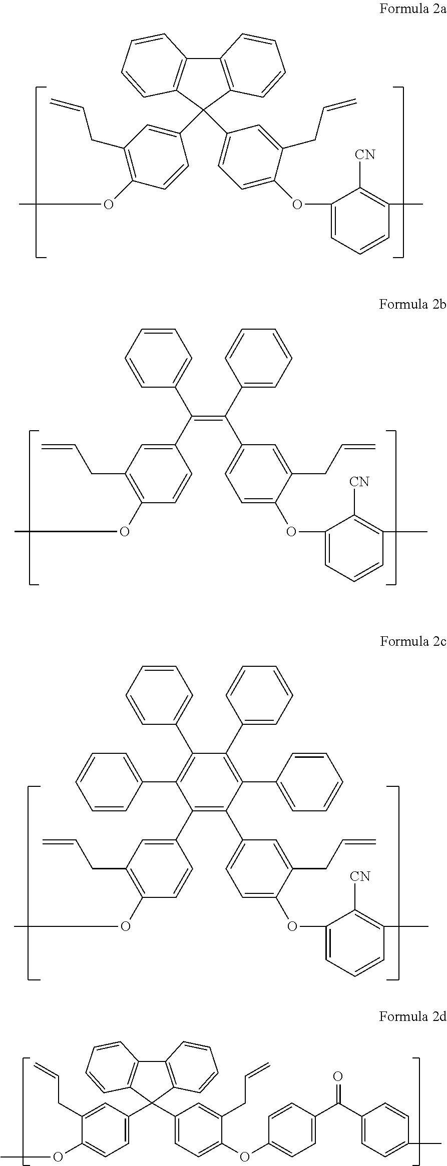

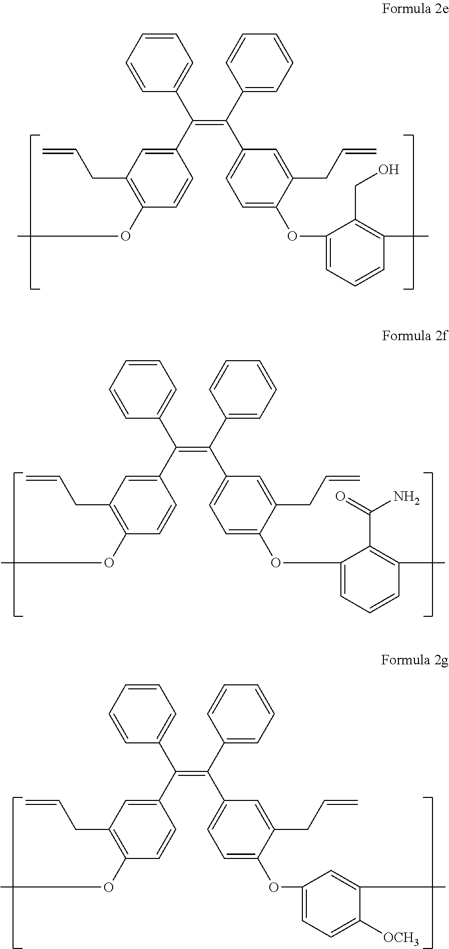

Examples of polymer represented by Formula 3 include the polymers represented by the following Formula 3a and Formula 3b.

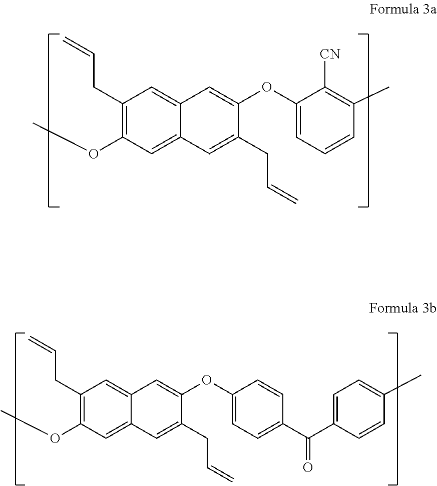

The phenolic self-crosslinking polymer of the present invention can be prepared by using a conventional polymerization method. For example, after obtaining a phenolic polymer with a condensation polymerization reaction, the hydrogen atom in hydroxyl group of the conventional phenolic polymer is substituted by cyanate group (Formula 1), alternatively alpha-hydrogen atom in hydroxyl group of the conventional phenolic polymer is substituted by allyl group and then the substituted phenolic polymer is condensation-polymerized to obtain the present phenolic self-crosslinking polymer (formulas 2 and 3) (see: following Manufacturing Examples 1 to 15). Mean molecular weight (Mw) of the present phenolic self-crosslinking polymer is, for example, 1,000 to 50,000, preferably 1,500 to 20,000, more preferably 2,000 to 5,000. When the mean molecular weight of the phenolic self-crosslinking polymer is beyond the above range, the thermal stability thereof may be reduced and a good planarization at a gab-filling step cannot be secured.

The resist-underlayer-film of the present invention is formed on a substrate such as silicon wafer by coating a composition of the resist-underlayer-film with spin coating or spin on carbon method, wherein the composition includes the phenolic self-crosslinking polymer and an organic solvent.

The composition of the resist-underlayer-film is coated (spin-coating) on a substrate. When the substrate is baked at 240 to 400° C., preferably 350 to 400° C., as shown in Reaction 1, the phenolic self-crosslinking polymer containing cyanate group (Formula 1) is self-crosslinking hardened in polycyanurate form. As shown Reaction 2, the phenolic self-crosslinking polymer containing allyl group (Formula 2 and Formula 3) is self-crosslinking hardened by tautomerization and diels-alder reaction of allyl group. Thus, the resist-underlayer film can formed without the additives for hardening the polymer such as thermal acid generator (TAG) or crosslinking agent, etc. In the following Reaction 1 and Reaction 2, only part where the reaction of phenolic self-crosslinking polymer happens can be shown.

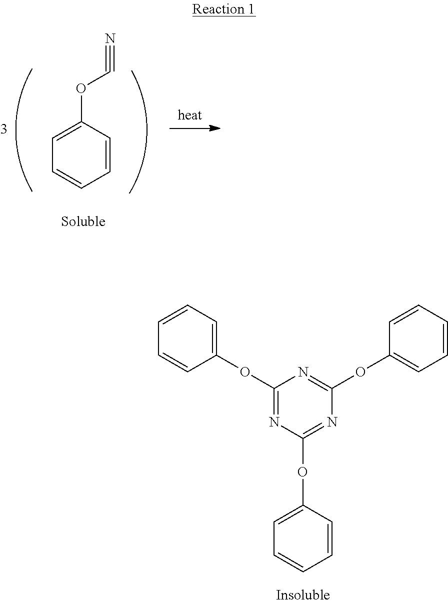

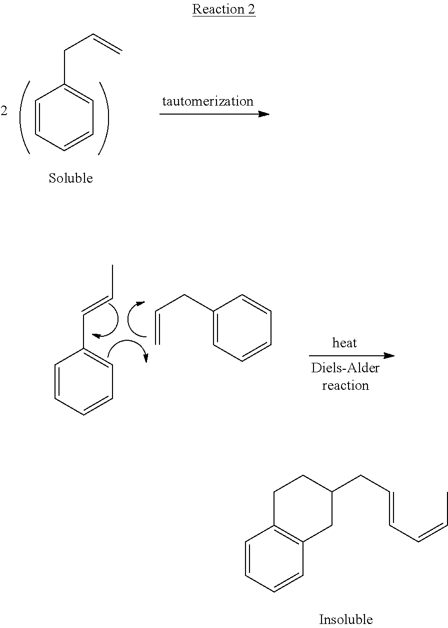

The organic solvent used in the present invention is a conventional organic solvent used for the resist-underlayer-film, which has solubility to the phenolic self-crosslinking polymer. Examples of the organic solvent include ketone including propylene glycol monomethyl ether acetate, cyclohexanone, ethyl lactate, methyl-2-amyl ketone etc, alcohol including as 3-methoxy butanol, 3-methyl-3-methoxy butanol, 1-methoxy-2-propanol, 1-ethoxy-propanol, etc, ethylene glycol monomethyl ether, or mixture thereof.

In the composition of the resist-underlayer-film, the amount of the phenolic self-crosslinking polymer is 1 to 50 weight %, preferably 2 to 30 weight %, more preferably 2 to 15 weight %. The amount of the organic solvent is 50 to 99 weight %, preferably 70 to 98 weight %, more preferably 85 to 98 weight %. If the amount of the phenolic self-crosslinking polymer is less than 1 weight % (the amount of the organic solvent is more than 99 weight %), the resist-underlayer-film with sufficient etch resistivity cannot be obtained. If the amount of the phenolic self-crosslinking polymer is more than 50 weight % (the amount of the organic solvent is less than 50 weight %), the resist-underlayer film with good uniformity cannot be obtained.

The resist-underlayer-film made of a composition of resist-underlayer-film according to the present invention can be formed by using a conventional resist-underlayer-film manufacturing method. For example, the composition of resist-underlayer film according to the present invention is coated (spin-coated) on a wafer, and the wafer is heated or baked at 240 to 400° C., preferably 350 to 400° C., to form the resist-underlayer-film of the present invention. If the temperature at baking step is less than 240° C., self-crosslinking ability of the present phenolic self-crosslinking polymer may be deteriorated and out-gassing at a backend process may be much. If the temperature at the baking step is more than 400° C., the thermal stability of the present resist-underlayer-film may be deteriorated because of thermal decomposition of a crosslinking part in the present phenolic self-crosslinking polymer.

Hereinafter, the preferable examples are provided for better understanding of the present invention. However, the present invention is not limited by the following examples.

### Manufacturing Example 1

### Preparation of Polymer Represented by Formula 1a

To a three-neck round-bottom 1 L-flask in which a reflux condenser and a Dean-Stark trap for removing water generated at a reaction are installed, added were 30 g (0.18 mol) of 4-phenylphenol, 15.9 g (0.18 mol) of paraformaldehyde, 3.4 g (0.02 mol) of p-toluenesulfonic acid (p-TSA) as an acid catalyst, and 70 g of tetrahydronaphthalene. The reaction mixture was stirred at 200° C. for 12 hours. After stirring the mixture, the stirred mixture was cooled, 100 g of tetrahydrofuran (solvent) was added to make the mixture be diluted. For removing unreacted monomer and low molecular weight compound of oligomer, the diluted mixture was slowly dropped into methanol so that the copolymer is precipitated and filtered. Washing off the filtered by using methanol was performed twice and then vacuum dehydration of the filtered by using vacuum oven at 50° C. was carried out for 8 hours. To a reactor of three-neck round-bottom 500 mL-flask, added were 40 g of copolymer vacuum-dehydrated and 40.9 g (0.39 mol) of cyanogens bromide, which were dissolved in 100 g of chloroform. The reactor was cooled to 0° C. by using iced water in nitrogen atmosphere. 39.06 g (0.39 mol) of triethylamine dissolved in 50 g of chloroform was slowly dropped to the reactor by using a funnel. The reactor was maintained at 0° C. for 30 minutes, heated to room temperature and then additional stirring was performed for 12 hours. After stirring, for removing a product from a side reaction, the product was slowly dropped into methanol to be precipitated and filtered. Washing off the filtered product by using methanol was performed three times. Then vacuum dehydration using vacuum oven at 100° C. was carried out for 12 hours, to obtain 37 g of polymer represented by Formula 1a (yield: 75.9%). The mean molecular weight (Mw) and polydispersity (PD) of the produced polymer were evaluated with gel permeation chromatography (GPC), by which Mw is 4,300 and PD is 2.21.

### Manufacturing Example 2

### Preparation of Polymer Represented by Formula 1b

Except for using 30 g (0.21 mol) of 2-naphtol instead of using 30 g (0.18 mol) of 4-phenylphenol, 35 g of polymer represented by Formula 1b was obtained according to the same manner of the above stated Manufacturing Example 1 (Yield: 71.8%, Mw=4,600, PD=2.41).

### Manufacturing Example 3

### Preparation of Polymer Represented by Formula 1e

Except for using 15 g (0.10 mol) of 4-phenylphenol and 17.7 g (0.10 mol) of 2-naphtol instead of using 30 g (0.18 mol) of 4-phenylphenol, 26 g of polymer represented by Formula 1e was obtained according to the same manner of the above stated Manufacturing Example 1 (Yield: 77.1%, Mw=4,200, PD=2.32).

### Manufacturing Example 4

### Preparation of Polymer Represented by Formula 1f

Except for using 40 g (0.14 mol) of 1,1′-binaphthyl-2,2′-diol instead of using 30 g (0.18 mol) of 4-phenylphenol, 26 g of polymer represented by Formula 1f was obtained according to the same manner of the above stated Manufacturing Example 1 (Yield: 64.7%, Mw=3,700, PD=2.50).

### Manufacturing Example 5

### Preparation of Polymer Represented by Formula 1 h

Except for using 30 g (0.086 mol) of 4,4′-(9-fluorenylidene)diphenol instead of using 30 g (0.18 mol) of 4-phenylphenol, and using 9.1 g (0.086 mol) of benzaldehyde instead of using 15.9 g (0.18 mol) of paraformaldehyde, 27 g of polymer represented by Formula 1 h was obtained according to the same manner of the above stated Manufacturing Example 1 (Yield: 71.1%, Mw=4,800, PD=2.46).

### Manufacturing Example 6

### Preparation of Polymer Represented by Formula 1i

Except for using 10.28 g (0.086 mol) of acetophenone instead of using 9.1 g (0.086 mol) of benzaldehyde, and the reaction (stirring) time being 48 hours, 23 g of polymer represented by Formula 1i was obtained according to the same manner of the above stated Manufacturing Example 5 (Yield: 57.1%, Mw=3,200, PD=2.16).

### Manufacturing Example 7

### Preparation of Polymer Represented by Formula 1j

Except for using 11.66 g (0.086 mol) of 4-methoxybenzaldehyde instead of using 9.1 g (0.086 mol) of benzaldehyde, 28.6 g of polymer represented by Formula 1j was obtained according to the same manner of the above stated Manufacturing Example 5 (Yield: 68.6%, Mw=3,700, PD=2.31).

### Manufacturing Example 8

### Preparation of Polymer Represented by Formula 1l

Except for using 17.66 g (0.086 mol) of anthracene aldehyde instead of using 9.1 g (0.086 mol) of benzaldehyde, and the reaction (stirring) time being 48 hours, 27.5 g of polymer represented by Formula 11 was obtained according to the same manner of the above stated Manufacturing Example 5 (Yield: 57.7%, Mw=3,800, PD=2.42).

### Manufacturing Example 9

### Preparation of Polymer Represented by Formula 1n

Except for using 30 g (0.082 mol) of (Z)-4,4′-(1,2-diphenylethane-1,2-diyl)diphenol instead of using 30 g (0.18 mol) of 4-phenylphenol, and using 17.66 g (0.086 mol) of anthracene aldehyde instead of using 15.9 g (0.18 mol) of paraformaldehyde, and the reaction (stirring) time being 48 hours, 30.12 g of polymer represented by Formula 1 n was obtained according to the same manner of the above stated Manufacturing Example 1 (Yield: 64.1%, Mw=4,700, PD=2.36).

### Manufacturing Example 10

### Preparation of Polymer Represented by Formula 1o

Except for using 30 g (0.053 mol) of 1,2,3,4-tetraphenyl-5,6-diphenolbenzene instead of using 30 g (0.18 mol) of 4-phenylphenol, and using 10.28 g (0.086 mol) of acetophenone instead of using 15.9 g (0.18 mol) of paraformaldehyde, and the reaction (stirring) time being 48 hours, 26 g of polymer represented by Formula 1o was obtained according to the same manner of the above stated Manufacturing Example 1 (Yield: 63.5%, Mw=4,200, PD=2.33).

### Manufacturing Example 11

### Preparation of Polymer Represented by Formula 2a

To a reactor of three-neck round-bottom 500 mL-flask in which a reflux condenser and a Dean-Stark trap for removing water generated at a reaction were installed, added were 50 g (0.14 mol) of 4,4′-(9-fluorenylidene)diphenol, 59.2 g (0.43 mol) of potassium carbonate, 150 g of acetone. The reaction mixture was stirred at 70° C. for 2 hours. After completing the stirring of the reaction mixture, 69.1 g (0.57 mol) of ally bromide dissolved in 50 g of acetone was slowly dropped to the reactor and a reaction was performed at 70° C. until the amount of 4,4′-(9-fluorenylidene)diphenol in the reactor is 1% or less than. The reactor was cooled to room temperature, 500 g of distilled water was added to the reactor and then was stirred. The product was filtered and the filtered material was additionally washed off twice by the mixture of distilled water and methanol whose ratio is 8:2 (distilled water: methanol), and then vacuum dehydration using vacuum oven at 50° C. was carried out for 8 hours to obtain 54 g of allyl group substituted allyloxyphenylfluorene (yield: 88%). The obtained allyloxyphenylfluorene was added to a round-bottom 250 mL-flask and then stirred at 240° C. for 2 hours in nitrogen atmosphere to produce quantitatively 4,4′-(9H-fluorene-9,9′-diyl)bis-2-allylphenol (allyl group substituted phenolic monomer). Then, to a three-neck round-bottom 500 mL-flask in which a reflux condenser and a Dean-Stark trap for removing water generated at a reaction were installed, added were 50 g (0.12 mol) of 4,4′-(9H-fluorene-9,9′-diyl)bis-2-allylphenol, 20.21 g (0.15 mol) of 2,6-difluororbenzonitrile, 19.3 g (0.14 mol) of potassium carbonate, 280 g of N-methylpyrrolidone and 45 g of toluene. The mixture was stirred at 190° C. for 8 hours. After completing the stirring, 500 g of distilled water was added to the reactor and stirred to produce precipitates. The precipitate was filtered. Then for removing monomer, catalyst and a product from a side reaction, washing off the stirred mixture was performed by using ethanol three times. Then vacuum dehydration using vacuum oven at 70° C. was carried out for 12 hours, to obtain 54 g of polymer represented by Formula 2a (yield: 87.7%). The mean molecular weight (Mw) and polydispersity (PD) of the produced polymer were evaluated with gel permeation chromatography (GPC), by which Mw is 5,600 and PD is 1.96.

### Manufacturing Example 12

### Preparation of Polymer Represented by Formula 2b

Except for using 40 g (0.11 mol) of (Z)-4,4′-(1,2-diphenylethylene-1,2-diyl)diphenol instead of using 50 g (0.14 mol) of 4,4′-(9-fluorenylidene)diphenol in order to prepare the allyl group substituted phenolic monomer, and then using 41 g (0.09 mol) of the allyl group substituted phenolic monomer, 48.4 g of polymer represented by Formula 2b was obtained according to the same manner of the above stated Manufacturing Example 11 (Yield: 87%, Mw=4,800, PD=1.86).

### Manufacturing Example 13

### Preparation of Polymer Represented by Formula 2c

Except for using 40 g (0.07 mol) of 1,2,3,4-tetraphenyl-5,6-diphenolbenzene instead of using 50 g (0.14 mol) of 4,4′-(9-fluorenylidene)diphenol in order to prepare the allyl group substituted phenolic monomer, and then using 37 g (0.06 mol) of the allyl group substituted phenolic monomer, 41.6 g of polymer represented by Formula 2c was obtained according to the same manner of the above stated Manufacturing Example 11 (Yield: 82%, Mw=4,300, PD=1.85).

### Manufacturing Example 14

### Preparation of Polymer Represented by Formula 2d

Except for using 56.75 g (0.26 mol) of 4,4′-difluorobenzophenone instead of using 20.21 g (0.15 mol) of 2,6-difluororbenzonitrile, 88.4 g of polymer represented by Formula 2d was obtained according to the same manner of the above stated Manufacturing Example 11 (Yield: 82.8%, Mw=4,700, PD=1.92).

### Manufacturing Example 15

### Preparation of Polymer Represented by Formula 3a

Except for using 40 g (0.25 mol) of 2,6-dinaphtol instead of using 50 g (0.14 mol) of 4,4′-(9-fluorenylidene)diphenol in order to prepare the allyl group substituted phenolic monomer, and then using 52 g (0.21 mol) of the allyl group substituted phenolic monomer, 60.4 g of polymer represented by Formula 3a was obtained according to the same manner of the above stated Manufacturing Example 11 (Yield: 87.6%, Mw=6,500, PD=1.94).

### Examples 1 to 15 and Comparative Examples 1 to 4

### Preparation of Composition of a Resist-Underlayer Film and Formation of the Resist-Underlayer-Film, and Evaluation Thereof

In accordance with the content in following Table 1, polymers prepared in Manufacturing Examples 1 to 15 were dissolved in propylene glycol monomethyl ether acetate (PGMEA) in the amount of 9% wt to prepare composition of resist-underlayer-films (Examples 1 to 15). m-cresol novolc resin whose Mw is 4,500 and P.D. is 3.4 or polyhydroxy styrene resin whose Mw is 4,800 and P.D. is 1.95 was dissolved in PGMEA in the amount of 7 wt %, and 7 parts by weight of cross-linking agent (Product Name: MX-270, Sanwa chemical Co., Ltd.) and 5 parts by weight of a thermal acid generator (product name: K-Pure TAG-2700, King Industries) were added, to prepare the compositions according to Comparative Examples 1 and 2. The amount of cross-linking agent and thermal acid generator is based on total composition of Comparative Examples 1 and 2. Alternatively, Comparative Examples 3 and 4 can be prepared by dissolving m-cresol novolc resin whose Mw is 4,500 and P.D. is 3.4 or polyhydroxy styrene resin whose Mw is 4,800 and P.D. is 1.95 in PGMEA in the amount of 7 wt %. Then the compositions prepared (Examples 1 to 15 and Comparative Examples 1 to 4) were filtered by using a 0.45 μm-filter.

Next, each of the prepared compositions of the resist-underlayer-film is spin-coated on a silicon wafer and was baked at 350° C. for 60 seconds to form a resist-underlayer-film having thickness of 3,000 Å. For examining the crosslinking ability of the phenolic self-crosslinking polymer (Manufacturing Examples 1 to 15), the wafer substrate on which the resist-underlayer-film was formed, was dipped in ethyl lactate solution for 1 minute and then was washed off by distilled water to remove the ethyl lactate. The substrate was again baked in a hot plate at 100° C. for 10 seconds and then the thickness of the resist-underlayer-film was measured, thereby evaluating a solubility (film thickness variation(ΔÅ)).

For evaluating the thermal resistivity of the resist-underlayer-film, sample was taken by scratching the wafer on which the resist-underlayer-film was formed and the mass loss amount (weight %) at 400° C. was measured with thermo gravimetric analysis, and the amount of out-gassing was measured with TDS (Thermo Desorption System).

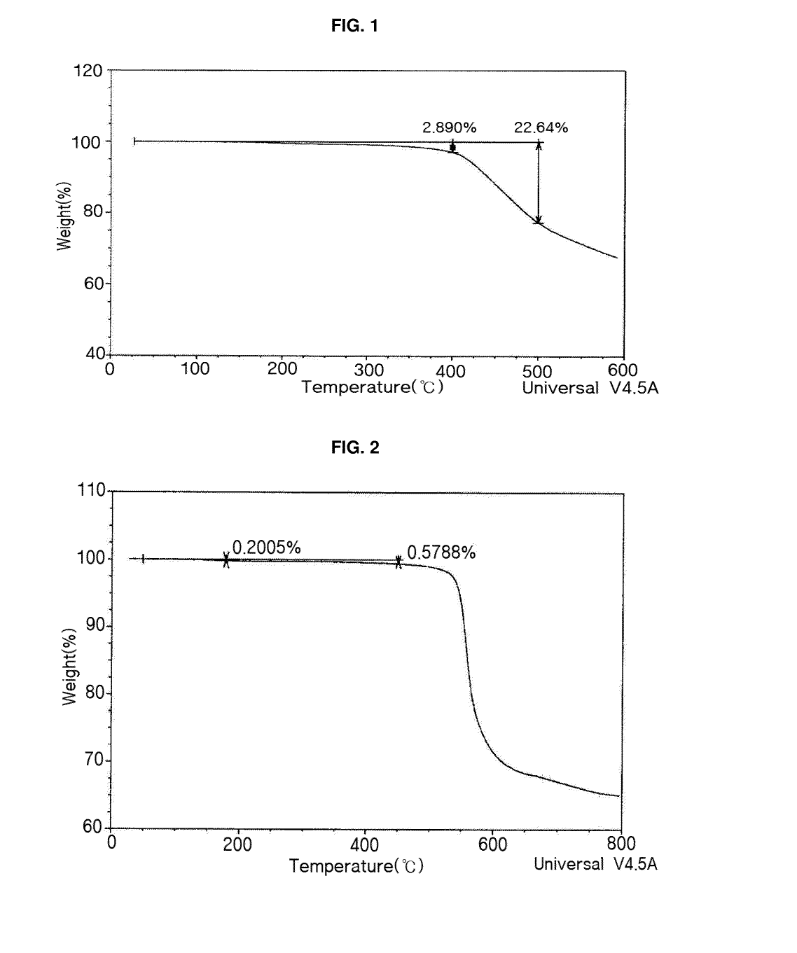

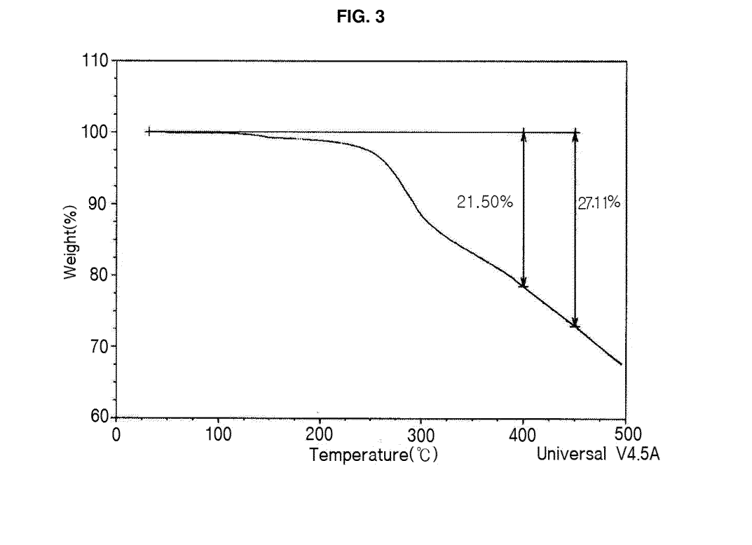

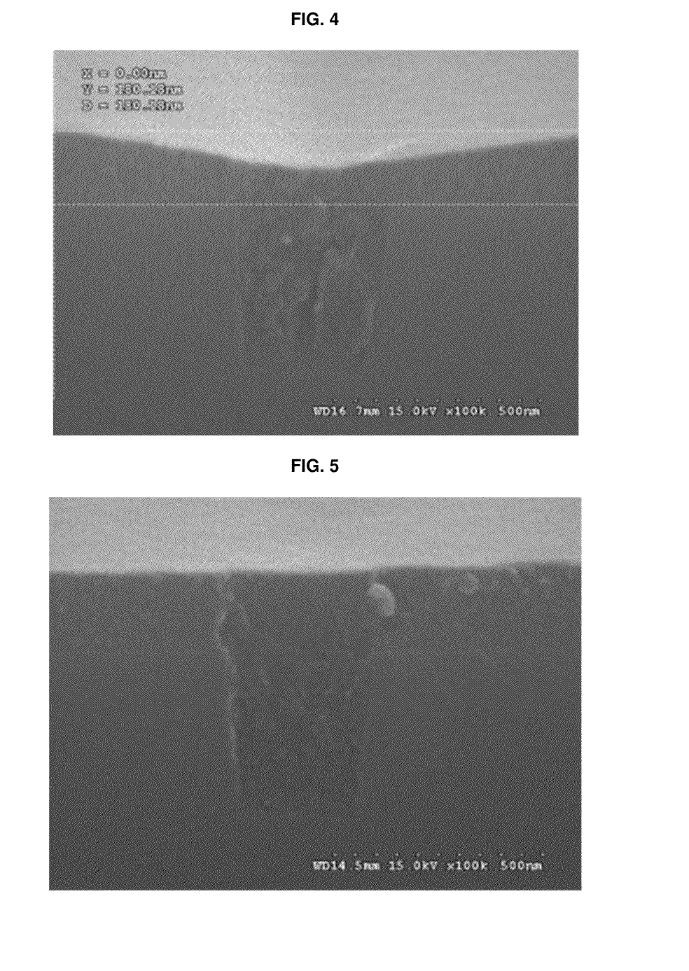

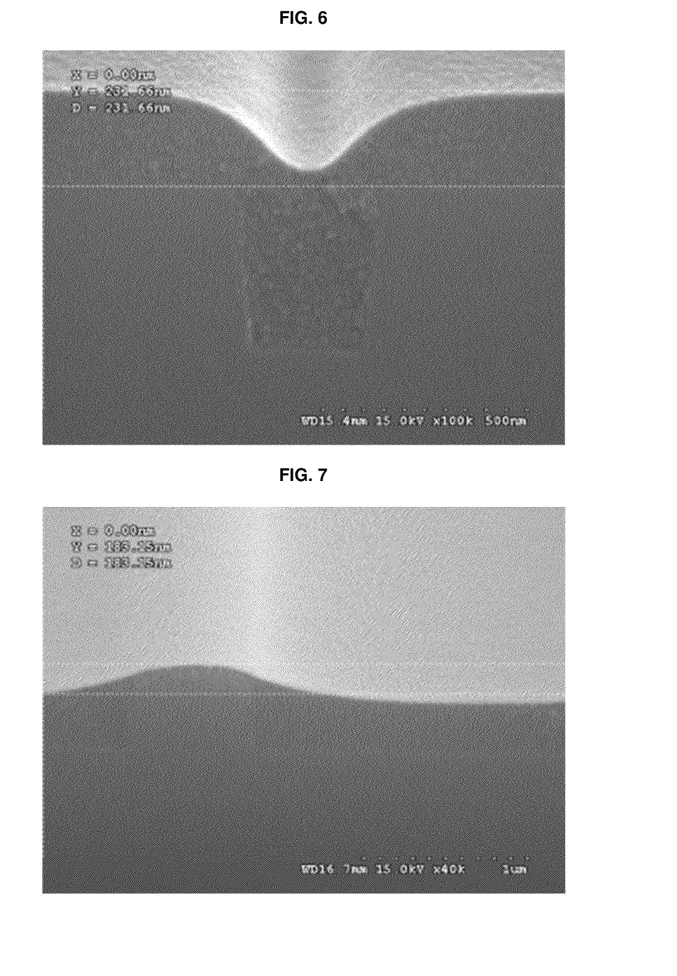

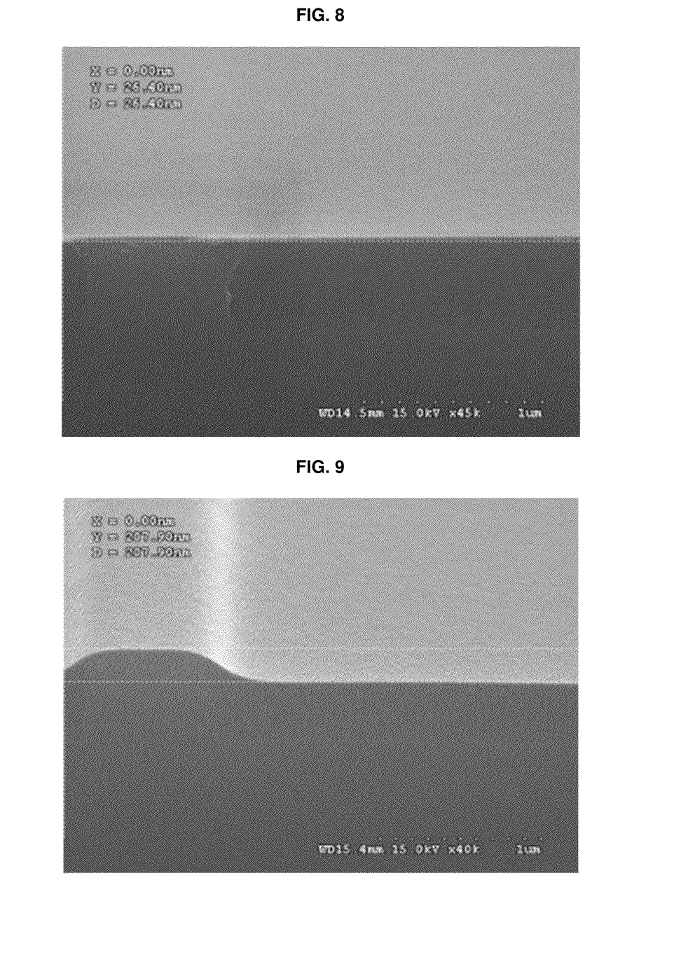

For evaluating the etch selectivity, wafer on which the resist-underlayer-film was coated, was subject to Si etching condition and C (carbon) etching condition and the thickness variation of resist-underlayer-film per unit second was measured. The results were shown in following Table 1 and Table 2. TGA graphs of resist-underlayer film samples according to Example 7, Example 11 and Comparative Example 1 of the present invention were shown in FIG. 1 to FIG. 3. Also, for confirming a gap-filling ability, the composition for resist-underlayer-film was coated on the wafer on which semiconductor patterns were formed by etching, and baking process at 350° C. was performed for 60 seconds. The profile of wafer was observed by using the FE-SEM (field emission scanning electron microscope, S-4200, Hitachi, Ltd.). FE-SEM (Field Emission Scanning Electron Microscope) photographs of silicon wafer where composition of the resist-underlayer-film according to Example 7, Example 11 and Comparative Example 1 of the present invention was coated and the ISO pattern and trench pattern were formed, were shown in FIG. 4 to FIG. 6 and FIG. 7 to FIG. 9, respectively.

TABLE 1

| | | | cross- | |
|---|---|---|---|---|
| | | thermal acid | linking | film |
| | polymer | generator | agent | variation (Δ Å) |
| Example 1 | Formula 1a | | | 6 |
| Example 2 | Formula 1b | | — | 4 |
| Example 3 | Formula 1e | — | — | 5 |
| Example 4 | Formula 1f | — | — | 7 |
| Example 5 | Formula 1h | — | — | 4 |
| Example 6 | Formula 1i | — | — | 8 |
| Example 7 | Formula 1j | — | — | 8 |
| Example 8 | Formula 1l | — | — | 6 |
| Example 9 | Formula 1n | — | — | 3 |
| Example 10 | Formula 1o | — | — | 7 |
| Example 11 | Formula 2a | — | — | 5 |
| Example 12 | Formula 2b | — | — | 7 |
| Example 13 | Formula 2c | — | — | 6 |
| Example 14 | Formula 2d | — | — | 4 |
| Example 15 | Formula 3a | — | — | 6 |
| Comparative | novolac resin | TAG-2700 | MX-270 | 6 |
| Example 1 | | | | |
| Comparative | polyhydroxy | TAG-2700 | MX-270 | 4 |
| Example 2 | styrene resin | | | |
| Comparative | novolac resin | — | — | 2842 |
| Example 3 | | | | |
| Comparative | polyhydroxy | — | — | 2980 |
| Example 4 | styrene resin | | | |

TABLE 2

| | | TGA | | | |
|---|---|---|---|---|---|
| | | (mass | | | |
| | | loss | | | |
| | | amount | | etching | |
| | | at | | amount (Å/sec) | |
| | | 400° C., | TDS | Si | |
| | polymer | wt %) | (μg/m³) | etch | C etch |
| Example 1 | Formula 1a | 4.4 | 6,426 | 40.4 | 102.6 |
| Example 2 | Formula 1b | 3.6 | 5,984 | 38.6 | 104.2 |
| Example 3 | Formula 1e | 4.6 | 6,245 | 36.2 | 101.2 |
| Example 4 | Formula 1f | 4.8 | 5,486 | 34.6 | 88.9 |
| Example 5 | Formula 1h | 2.9 | 4,469 | 36.2 | 91.6 |
| Example 6 | Formula 1i | 3.3 | 4,395 | 38.3 | 94.2 |
| Example 7 | Formula 1j | 2.8 | 4,128 | 35.1 | 88.4 |
| Example 8 | Formula 1l | 3.2 | 4,467 | 37.8 | 95.3 |
| Example 9 | Formula 1n | 2.7 | 4,623 | 37.2 | 92.4 |
| Example 10 | Formula 1o | 2.9 | 4,295 | 31.7 | 86.7 |
| Example 11 | Formula 2a | 0.8 | 3,512 | 34.9 | 89.0 |
| Example 12 | Formula 2b | 1.4 | 3,675 | 32.8 | 94.8 |
| Example 13 | Formula 2c | 0.6 | 3,849 | 36.4 | 89.5 |
| Example 14 | Formula 2d | 2.6 | 4,075 | 40.2 | 96.1 |
| Example 15 | Formula 3a | 1.2 | 3,046 | 36.8 | 95.3 |
| Comparative | novolac resin | 21.5 | 45,133 | 33.6 | 40.6 |
| Example 1 | | | | | |
| Comparative | polyhydroxy | 27.2 | 38,246 | 33.7 | 98.5 |
| Example 2 | styrene resin | | | | |
| Comparative | novolac resin | 70.6 | Not | 40.6 | 38.9 |
| Example 3 | | | evaluated | | |
| Comparative | polyhydroxy | 80.2 | Not | 39.74 | 97.8 |
| Example 4 | styrene resin | | evaluated | | |

From Table 1 and Table 2, the phenolic self-crosslinking polymer of the present invention has a good thermal stability and can be hardened without additives for polymer hardening (cross-linking) such as a cross linking agent or TAG etc, at a baking step. Also, the composition of the resist-underlayer film containing the phenolic self-crosslinking polymer and the organic solvent is suitable for a composition of spin-on-carbon underlayer which requires the thermal stability. The composition of the resist-underlayer film of the present invention has relatively high etch selectivity and excellent planarization at a gab-filling step. In using the composition of the resist-underlayer-film, Out-gassing generated at hardening process or backend process is very little because the composition of the present invention has no curing agent.

What is claimed is:

1. A phenolic self-crosslinking polymer selected from a group consisting of a polymer represented by following Formula 1, a polymer represented by following Formula 2 and a polymer represented by following Formula 3. 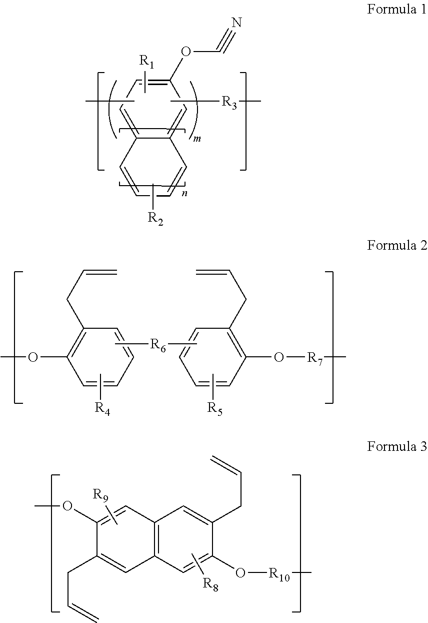
wherein in Formulas 1 to 3, R1, R2, R4, R5, R8 and R9 each is independently a hydrogen atom or chain type, branch type, single ring type or multi-ring type, saturated or unsaturated hydrocarbon group of 1 to 20 carbon atoms, which contains or does not contain a hetero atom, R3, R7 and R10 each is independently chain type, branch type, single ring type or multi-ring type, saturated or unsaturated hydrocarbon group of 1 to 30 carbon atoms, which contain or does not contain a hetero atom, R6 is independently chain type, branch type, single ring type or multi-ring type, saturated or unsaturated hydrocarbon group of 1 to 40 carbon atoms, m is 1 or 2, and when m is 2, each repeating unit of m is connected to each other directly or through chain type, branch type, single ring type or multi-ring type, saturated or unsaturated hydrocarbon group of 1 to 40 carbon atoms, and n is an integer of 0 to 100.

2. The phenolic self-crosslinking polymer of claim 1, wherein the polymer represented by Formula 1 includes a polymer selected from a group consisting of polymers represented by following Formula 1a to Formula 10, the polymer represented by Formula 2 includes a polymer selected from a group consisting of polymers represented by following Formula 2a to Formula 2g, and the polymer represented by Formula 3 includes a polymer selected from a group consisting of polymers represented by following Formula 3a and Formula 3b,

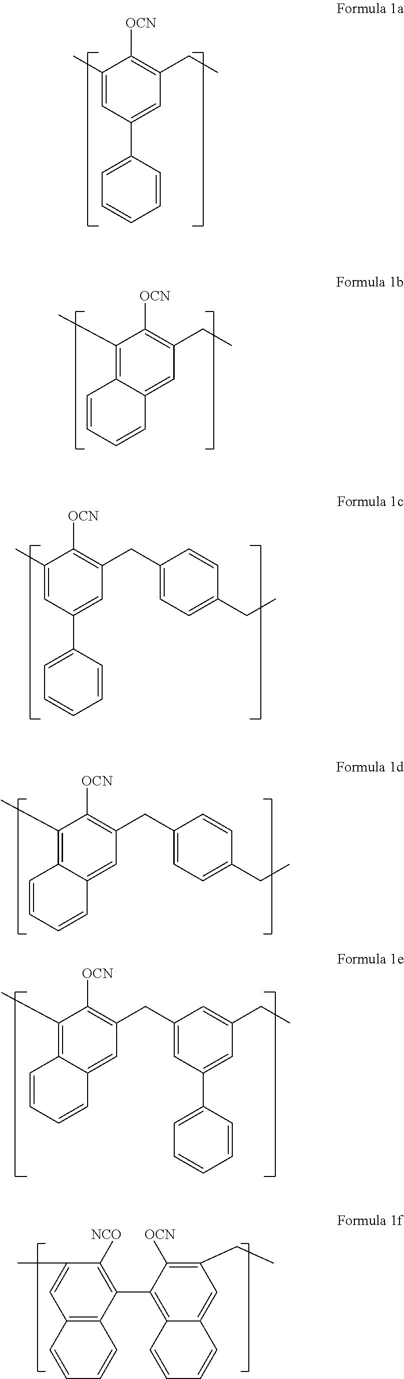

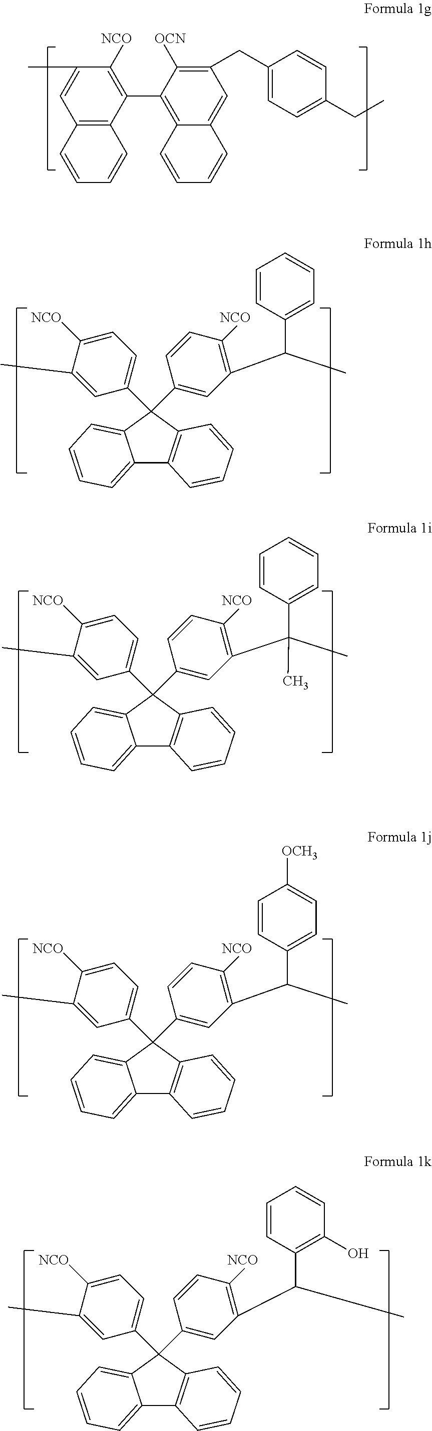

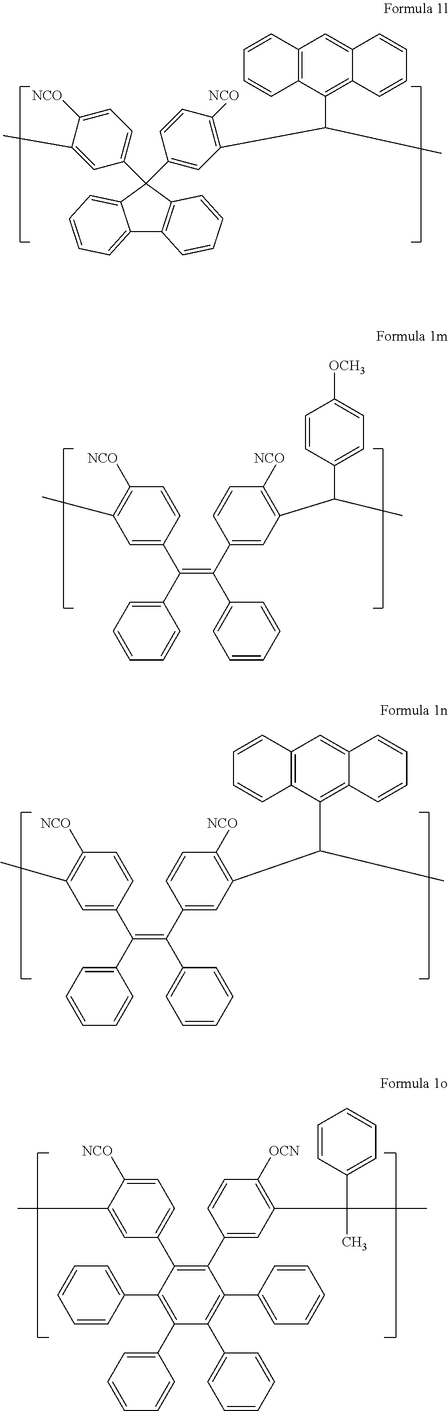

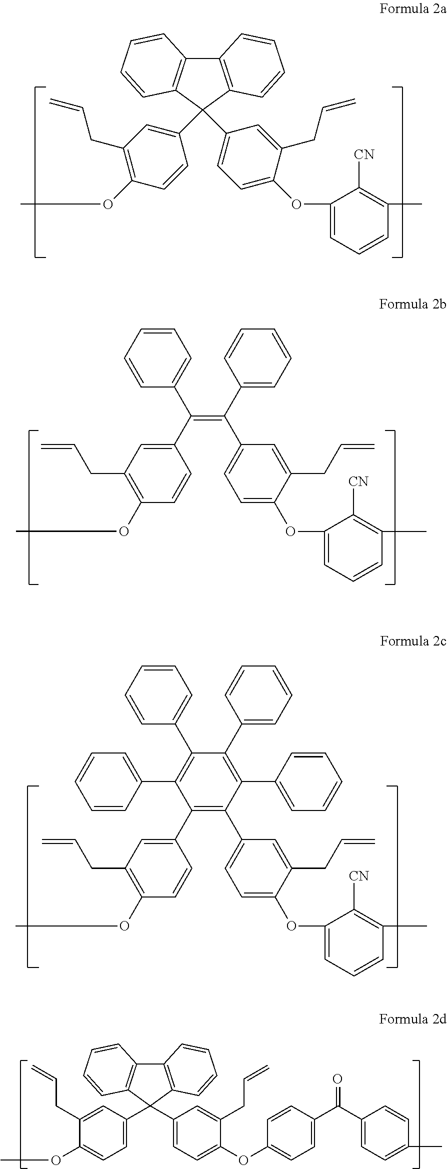

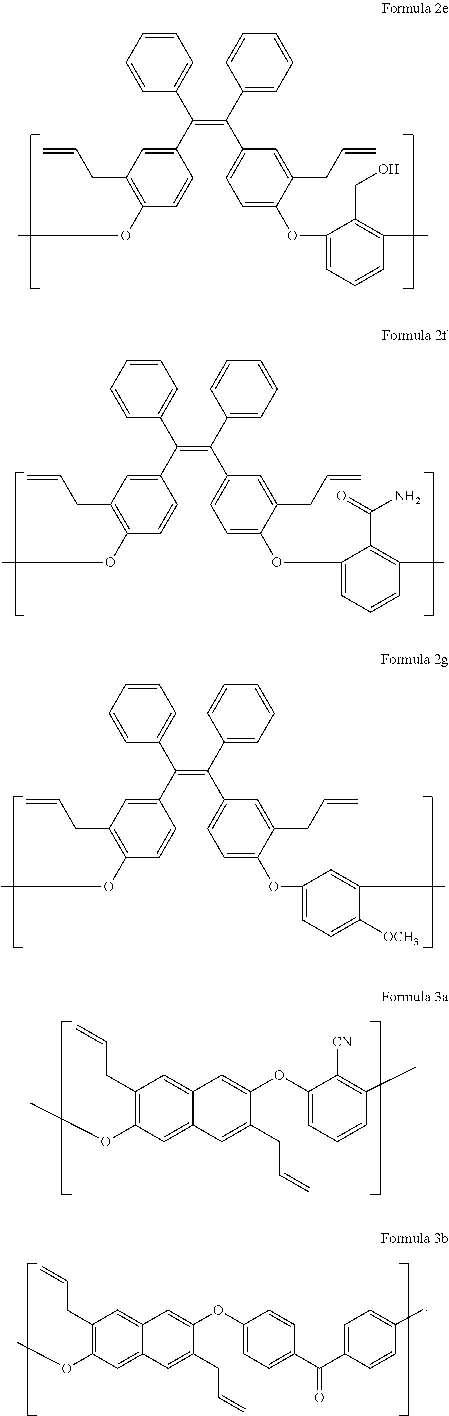

3. The phenolic self-crosslinking polymer of claim 1, wherein molecular weight of the phenolic self-crosslinking polymer is 1,000 to 50,000.

4. A composition of resist-underlayer-film, comprising a phenolic self-crosslinking polymer; and an organic solvent,
the phenolic self-crosslinking polymer being selected from a group consisting of a polymer represented by following Formula 1, a polymer represented by following Formula 2 and a polymer represented by following Formula 3, 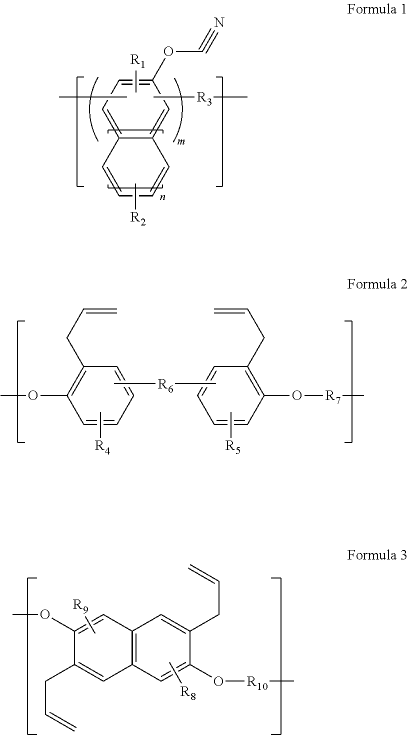
wherein in Formulas 1 to 3, R1, R2, R4, R5, R8 and R9 each is independently a hydrogen atom or chain type, branch type, single ring type or multi-ring type, saturated or unsaturated hydrocarbon group of 1 to 20 carbon atoms, which contains or does not contain a hetero atom, R3, R7 and R10 each is independently chain type, branch type, single ring type or multi-ring type, saturated or unsaturated hydrocarbon group of 1 to 30 carbon atoms, which contain or does not contain a hetero atom, R6 is independently chain type, branch type, single ring type or multi-ring type, saturated or unsaturated hydrocarbon group of 1 to 40 carbon atoms, m is 1 or 2, and when m is 2, each repeating unit of m is connected to each other directly or through chain type, branch type, single ring type or multi-ring type, saturated or unsaturated hydrocarbon group of 1 to 40 carbon atoms, and n is an integer of 0 to 100.

5. The composition of resist-underlayer film of claim 4, wherein amount of the phenolic self-crosslinking polymer is 1 to 50 weight % and amount of the organic solvent is 50 to 99 weight %.

6. The composition of resist-underlayer film of claim 4, wherein the organic solvent is selected from a group consisting of propylene glycol monomethyl ether acetate, cyclohexanone, ethyl lactate, methyl-2-amyl ketone, 3-methoxy butanol, 3-methyl-3methoxy butanol, 1-methoxy-2-propanol, 1-ethoxy-2-propanol, ethylene glycol monomethyl ether and mixture thereof.

7. A method for forming resist-underlayer-film, comprising the steps of:
coating, on a wafer, a composition containing a phenolic self-crosslinking polymer and an organic solvent; and
heating the wafer at 240 to 400° C.,
the phenolic self-crosslinking polymer being selected from a group consisting of a polymer represented by following Formula 1, a polymer represented by following Formula 2 and a polymer represented by following Formula 3, 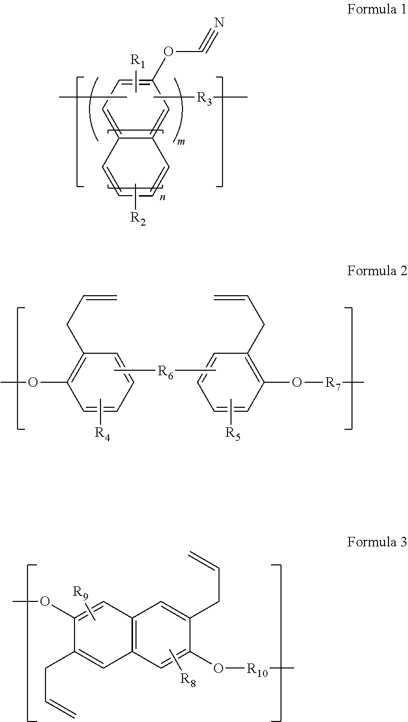
wherein in Formulas 1 to 3, R1, R2, R4, R5, R8 and R9 each is independently a hydrogen atom or chain type, branch type, single ring type or multi-ring type, saturated or unsaturated hydrocarbon group of 1 to 20 carbon atoms, which contains or does not contain a hetero atom, R3, R7 and R10 each is independently chain type, branch type, single ring type or multi-ring type, saturated or unsaturated hydrocarbon group of 1 to 30 carbon atoms, which contain or does not contain a hetero atom, R6 is independently chain type, branch type, single ring type or multi-ring type, saturated or unsaturated hydrocarbon group of 1 to 40 carbon atoms, m is 1 or 2, and when m is 2, each repeating unit of m is connected to each other directly or through chain type, branch type, single ring type or multi-ring type, saturated or unsaturated hydrocarbon group of 1 to 40 carbon atoms and n is an integer of 0 to 100.
